(19) United States
(12) Patent Application Publication
(10) Pub. No.: US 2014/0311546 A1
(43) Pub. Date: Oct. 23, 2014

(54) METHOD FOR DISCONNECTING A PHOTOVOLTAIC ASSEMBLY AND PHOTOVOLTAIC ASSEMBLY

(71) Applicants: Ingmar Kruse, Nuernberg (DE); Roustam Asimov, Minsk (BY)

(72) Inventors: Ingmar Kruse, Nuernberg (DE); Roustam Asimov, Minsk (BY)

(21) Appl. No.: 13/993,981

(22) PCT Filed: Dec. 13, 2011
(86) PCT No.: PCT/EP2011/006283

§ 371 Date: Aug. 9, 2013

(30) Foreign Application Priority Data
Feb. 13, 2010 (DE) 10 2010 054 354.3

(51) Int. Cl. H01L 31/05; H01L 31/18

(52) U.S. Cl. CPC H01L 31/05; H01L 31/18
USPC 136/244; 29/25.01

(57) ABSTRACT

A method for disconnecting a photovoltaic assembly, wherein the photovoltaic assembly includes the following: a string having a plurality of photovoltaic modules having a plurality of solar cells, an electrical line, which connects the individual photovoltaic modules to one another to form the string and serve the purpose of conducting the current produced by the individual solar cells in the photovoltaic modules to a common inverter. The photovoltaic assembly is disconnected by a disconnection signal in a hazard situation. Furthermore, in order to ensure increased safety in an emergency situation, provision is made for the disconnection signal to be conducted via the electrical line to the individual photovoltaic modules in the string, for the disconnection signal to be detected at the respective photovoltaic module and for the respective photovoltaic module to be disconnected via a switching device arranged at the respective photovoltaic module.

The present invention relates to a method for disconnecting a photovoltaic assembly in an emergency situation and to a photovoltaic assembly which has a corresponding disconnecting device.

### TECHNICAL BACKGROUND

Photovoltaic assemblies are generally located on roofs of residential and industrial buildings. In the event of a fire, extinguishing water is generally used by firefighters which can result in personal injury when a photovoltaic assembly is active. The jet of extinguishing water acts as an arrester for the current generated by the photovoltaic assembly. As a result, it is desirable to disconnect the photovoltaic assembly as quickly as possible in such an emergency situation.

### Closest Prior Art

DE 10 2005 018 173 A1 discloses a method for disconnecting photovoltaic assemblies in an emergency situation. For this purpose, an emergency switch is provided in the electrical connecting line between the rectifier and the individual strings of the photovoltaic modules, which emergency switch can be actuated via a switching device. The actuation signal is applied via a control line connected to the switching device. The electrical circuit is therefore interrupted directly upstream of the inverter. Nevertheless, an electrical charge is present on the individual photovoltaic modules, and this electrical charge can flow away via a jet of extinguishing water. DE 10 2005 012 213 A1 discloses a connection circuit for the electrical connection of solar cells in a solar cell module, in which the connection circuit has, as protection device, a controlled electronic switching arrangement. This is configured in such a way that, in the event of a disconnected solar cell, it acts as current bypass for the disconnected solar cell.

### Problem of the Present Invention

The problem of the present invention consists in providing a method for disconnecting a photovoltaic assembly and a corresponding photovoltaic assembly which provides increased safety for firefighters during use with comparatively simple technical means.

### Solution to the Problem

The above problem is solved with the method in accordance with the generic type in that the disconnection signal is conducted via the electrical line means to the individual photovoltaic modules in the string, the disconnection signal is detected at the respective photovoltaic module, and the respective photovoltaic module is disconnected via a switching device arranged at the respective photovoltaic module. The disconnection of the individual photovoltaic modules has the effect that it is no longer possible for any current to flow out of the junction box of the respective photovoltaic module into the connecting lines of the photovoltaic modules. If a current still flows away at all, such a level of current does not represent a hazard. This results in a considerable increase in the safety for firefighters when extinguishing a fire.

In accordance with an expedient configuration of the present invention, the disconnection takes place by interrupting the electrical line means on the photovoltaic module, preferably in the junction box thereof. A current flow out of the junction box into the wiring of the string is thus prevented.

In accordance with an alternative configuration of the present invention, a short circuit is produced in the region of the respective photovoltaic module and a current flow is thus prevented.

Preferably, all of the photovoltaic modules are disconnected by means of the disconnection signal in the method according to the invention. Expediently, a preferably modulated voltage signal or current signal is used as disconnection signal. The form of the disconnection signal can vary as long as it is ensured that the disconnection signal can be distinguished from other voltage signals occurring in the region of the photovoltaic module. For example, the disconnection signal may be voltage pulses with a relatively high frequency.

In the case of status parameter determination of the respective photovoltaic module by a test circuit associated with the respective photovoltaic module, the disconnection signal can be detected as further signal which can be sensed by the test circuit. This makes it possible to extend an existing installation by a subroutine of the microcontroller controlling the test circuit in respect of the desired functionality.

In order to generate the disconnection signal, it is possible to generate said disconnection signal via an external signal generator, which is connected onto the electrical line means. This is possible since the disconnection signal can be fed into the electrical line means at any desired point. This case is expedient when the feed is intended to take place at a position which is independent of the position of the inverter.

Such a signal generator can in particular feed a load, preferably a voltage in the form of a clocked amplitude sequence, into the electrical line means as modulated signal.

Alternatively, the inverter itself can likewise generate such a disconnection signal by virtue of the control of the current/voltage characteristic (MPP tracking) at the inverter being used for generating the disconnection signal. In this case, the inverter generates a signal which is implausible for the control of the current/voltage characteristic. This alternative configuration has the advantage that it can be achieved in a simple manner via an additional software routine of the microcontroller control.

By virtue of the fact that the test device of the respective photovoltaic module has a test circuit for the status determination, which test circuit at the same time acts as a device for receiving the disconnection signal, the emergency disconnection can be implemented as an additional functionality of the test device, which simplifies the design and reduces costs.

The same applies when the control of the inverter has control software for the current/voltage characteristic (MPP tracking) and a subroutine of this software is provided for generating the disconnection signal.

Alternatively, a separate signal generator can feed a disconnection signal into the electrical line means at any desired point on the electrical line means.

The signal generator comprises, for example, a load element, for example a capacitor, and an active element, such as a transistor, for example, which feeds a voltage, for example, in the desired modulated signal form into the electrical line means. Alternatively, a modulated current signal can also be provided as disconnection signal.

Finally, the present invention relates to a photovoltaic element for use in a photovoltaic assembly as claimed in at least one of claims 8-14.

The present invention furthermore comprises a photovoltaic assembly in accordance with the preamble of claim 8, which has a device for generating a disconnection signal which is common to the photovoltaic modules, wherein a switching device is associated with each of the photovoltaic modules, by means of which switching device the respective photovoltaic module can be disconnected.

The switching device can expediently be a switch which interrupts the electrical line means preferably within the junction box of the photovoltaic module.

Alternatively, the switching device may be a switching device in the form of a short-circuiting switch.

### DESCRIPTION OF THE INVENTION WITH REFERENCE TO EXEMPLARY EMBODIMENTS

Expedient configurations of the present invention are explained in more detail below with reference to drawings, in which:

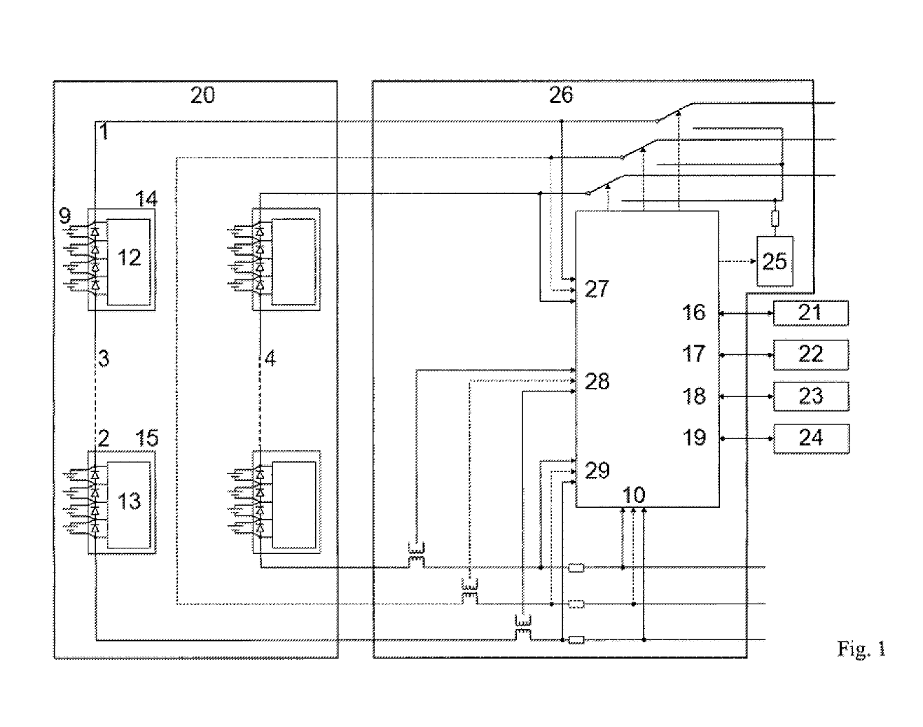

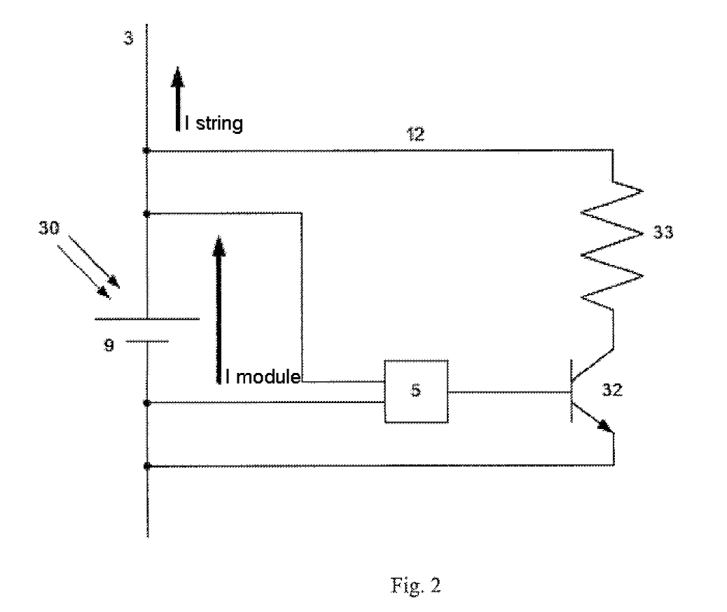

FIG. 1 shows a schematic overall illustration of a photovoltaic assembly,

FIG. 2 shows a very simplified schematic basic sketch of a photovoltaic module in accordance with the assembly shown in FIG. 1,

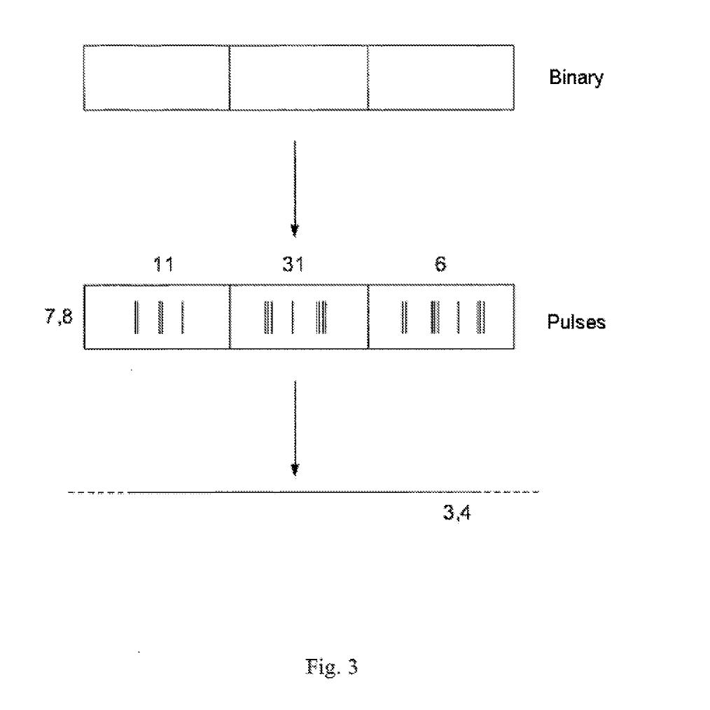

FIG. 3 shows a very simplified schematic illustration of data blocks for transmission to the evaluation unit,

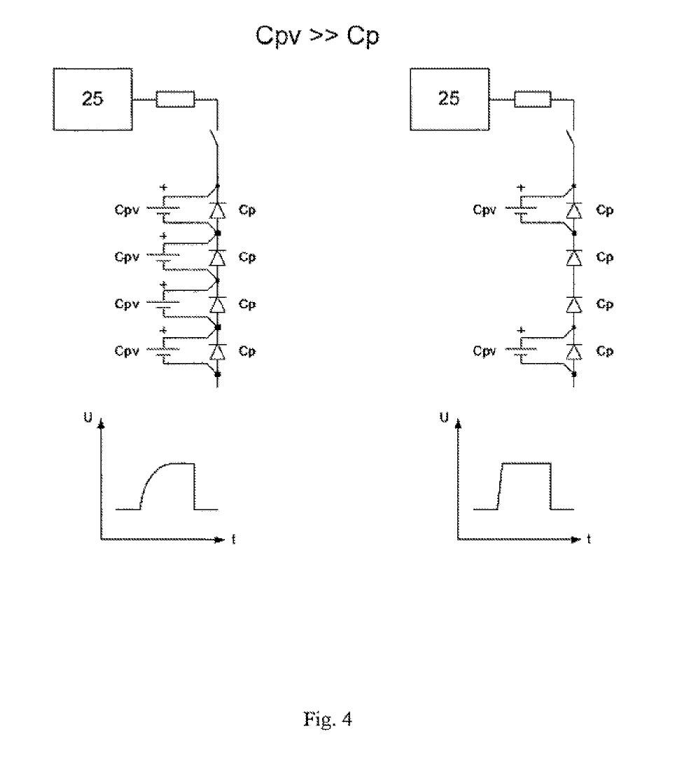

FIG. 4 shows a very simplified basic circuit diagram illustration for ensuring anti-theft monitoring,

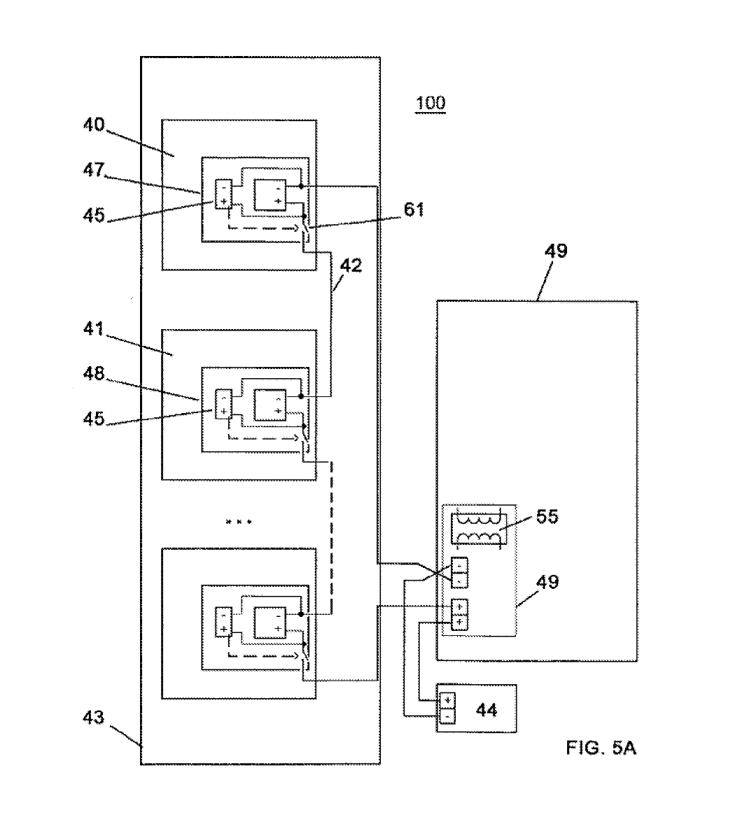

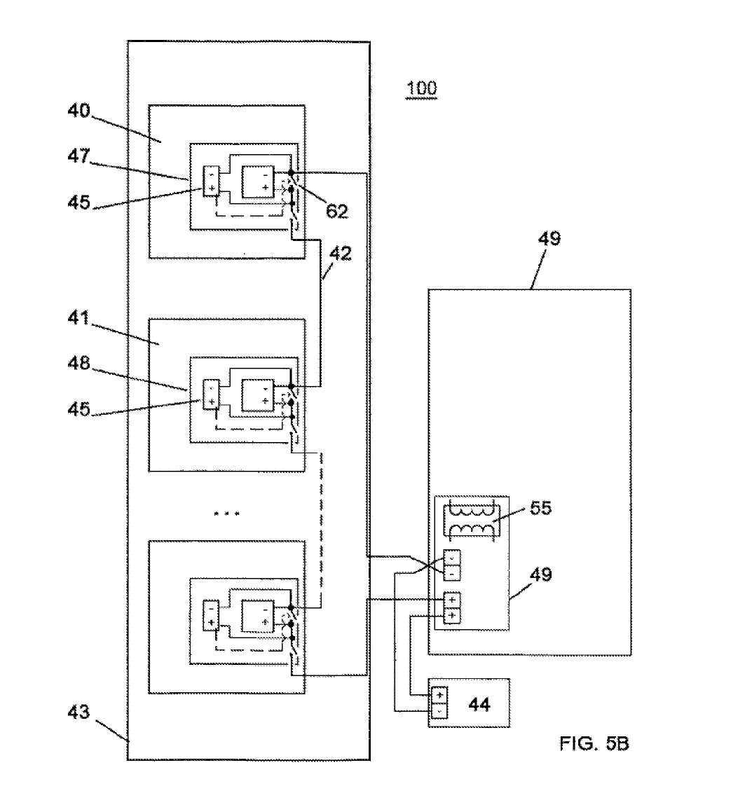

FIG. 5 shows a very simplified schematic illustration of a first configuration of the invention using an interrupter switch (FIG. 5A) and a further configuration of the invention using a short-circuiting switch (FIG. 5B),

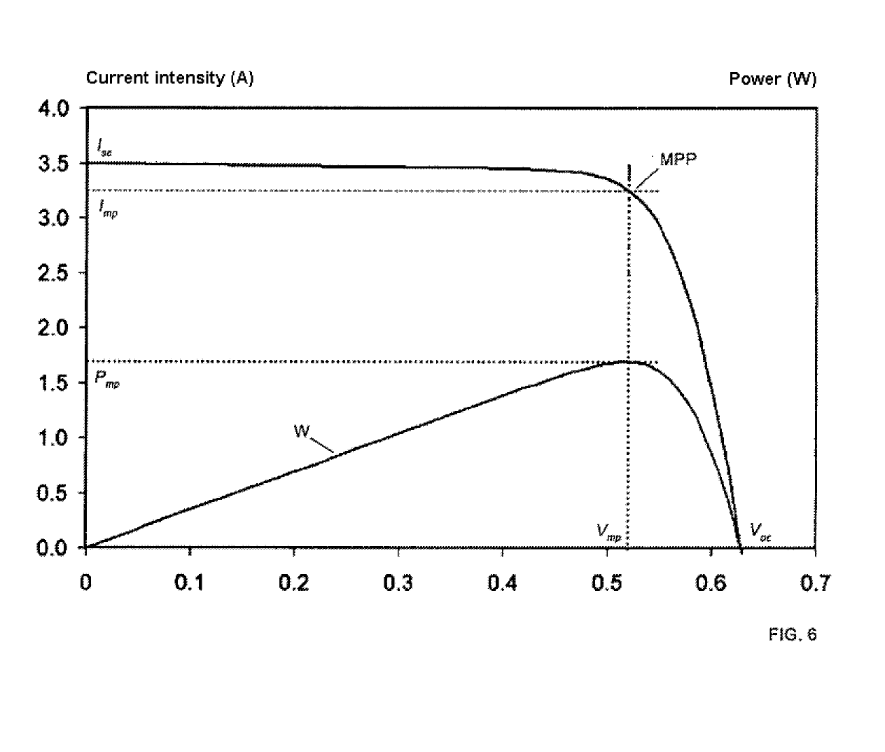

FIG. 6 shows an illustration of the MPP point as part of the so-called MPP tracking, and

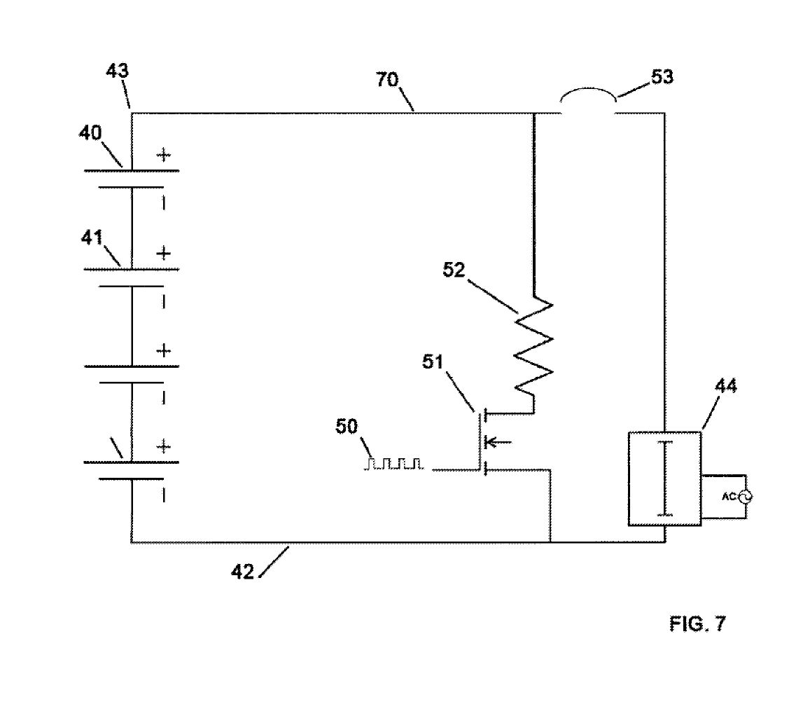

FIG. 7 shows a very simplified schematic illustration of an example of a signal generator for generating the disconnection signal.

FIG. 1 shows a photovoltaic assembly 20 for generating electrical energy from solar energy. The photovoltaic assembly comprises a multiplicity of photovoltaic modules 1, 2, which are connected to one another via conventional electrical line means 3 and 4, respectively, in the form of a series (series circuit). The arrangement shown in the illustration in FIG. 1 comprises in total two series of photovoltaic modules, wherein the photovoltaic modules 1, 2 are connected to one another via the electrical line means 3, and the further photovoltaic modules illustrated in FIG. 1 are connected to one another via the electrical line means 4. It is indicated in FIG. 1 that further series circuits of photovoltaic modules are also conceivable.

The electrical line means 3 and 4 serve the purpose of conducting the current generated by the multiplicity of photovoltaic cells 9 of the respective photovoltaic module, for example 1 or 2, to a (in each case not illustrated) consumer, store or the like.

A test device 12 and 13 is associated with each photovoltaic module, for example 1 or 2. This test device 12, 13 is expediently located in the so-called junction box 14, 15, which connects the photovoltaic module to the electrical line means 3 and 4, respectively.

A central evaluation unit 10 is connected to the respective photovoltaic module, for example 1 or 2, of the photovoltaic assembly 20 via the appropriate electrical line means, for example 3 or 4. The evaluation unit 10 is provided for receiving information relating to the status (for example voltage, temperature and/or current intensity etc.) of the individual photovoltaic modules, for example 1 or 2, for evaluating this information and, in the event of an emergency, introducing certain measures (replacement of photocells or photovoltaic modules, trimming disruptive vegetation, cleaning the surfaces, eliminating damage to lines resulting from storms etc.).

The evaluation unit has different interfaces 16, 17, 18, 19 for connecting the evaluation unit 10 to the desired data output or data transmission devices, such as a com port 21, an optical interface 22, an Internet connection 23 and/or a GSM connection 24, for example.

An energy source 25 is provided for operating the evaluation unit 10. It is possible by means of a switching device 26 to connect the evaluation unit 10 onto the respective series of individual photovoltaic modules, for example 1 or 2.

The evaluation unit 10 has inputs (voltage input 27), (data input 28) and (current signal input 29). The abovementioned inputs 27 to 29 are connected to the electrical line means 3.

The energy for operating the test device 12, 13 is made available in accordance with the invention directly in the form of electrical energy from the photovoltaic modules 1, 2. An additional energy source or additional supply wiring is therefore not necessary in the region of the photovoltaic modules. Instead, the already existing standard wiring or cabling can be used.

However, if there is no sunlight, there can be no power available for the test device 12, 13. However, this is acceptable since the determination of the status parameters of the respective photovoltaic module during a time when sunlight is available is sufficient.

FIG. 2 shows the simplified basic circuit for determining at least one status parameter of the respective photovoltaic module, for example of the photovoltaic module 1 illustrated in FIG. 2. For reasons of simplicity, FIG. 2 shows only one photovoltaic cell 9, but in reality a plurality of photovoltaic cells 9 are associated with a circuit illustrated in FIG. 2. As can be seen from FIG. 2, when photons 30 are incident within the photovoltaic cell 9, a current I is generated which is fed into the electrical line 3.

The test device 12 or 13 furthermore comprises a microcontroller 5, which, provided with a dedicated generator (not illustrated) and a dedicated control software, can implement the required operations. The microcontroller 5 comprises means for status parameter determination, such as a device for sensing the electrical voltage, for example. The test device 12 or contains means for generating current pulses which can be read as data at the end of the electrical line means 3. For this purpose, the test device 12 has a shunt circuit, which has a resistor 33 and a transistor 32, which is actuated by the microcontroller 5. A current drop pulse is generated in the electrical line means 3 by this circuit.

In the microcontroller 5, a binary code structure is converted into a particular sequence of corresponding current drop pulses with the aid of a suitable pattern.

The use of the shunt makes it possible to generate a data signal by current modulation. By means of the microcontroller 5 in combination with the shunt, current pulses are generated as data elements and fed into the electrical line means 3 for transmission of the data.

In addition to the status data to be transmitted, the individual serial number of the photovoltaic module 1 or 2 and plausibility data are also coded in this way and fed into the electrical line means.

The microcontroller 5 generates current pulses from a binary bit sequence corresponding to the circuit possibility illustrated in FIG. 2, and said current pulses are fed into the electrical line means 3. As can be seen from FIG. 3, a data block, for example the data block 7, comprises data elements 11 which identify the respective photovoltaic module, for example 1, data elements 31 relating to the respective status data of the associated photovoltaic module such as, for example, voltage etc. and data elements 6 which contain plausibility data. The generation and transmission of these data is performed in the form of pulses in time windows (frames). The pulse or bit sequence within such a time window or data element 11 or 31 is generated in a pseudo-random form in order to give rise to lower electromagnetic induction (EMI) and, as a result, to limit the noise. This can take place, for example, by virtue of the fact that a “regular” bit is replaced by a bit sequence, i.e. a plurality of bits, to be generated by the microcontroller, wherein this sequence can be read in turn by the evaluation unit. The order of the bits in this bit sequence can be generated in a pseudo-random form, for example. The order of a pseudo-random number is the order of the numbers which can be calculated by any defined arithmetic process, and this can be used for the reading.

The data transmission is unidirectional. The photovoltaic modules of a photovoltaic assembly 20 transmit their data blocks, for example 7, independently of one another, with the result that the probability of collision between data blocks within the electrical line means 3 or 4, which connect the individual photovoltaic modules, for example 1 or 2, to one another, is greater than 0. The abovementioned independent transmission of the data blocks 7, 8 means that the transmission of the data sets from one photovoltaic module over the electrical line means 3 or 4 does not take account of whether another or several other photovoltaic modules is/are not also transmitting its/their data blocks at the same time. No addressing of the individual photovoltaic modules from the direction of the evaluation unit 10 takes place. The microcontroller 5 is not addressed by the evaluation unit, but is autonomous.

Each microcontroller 5 waits for a delay time T_{w}, which is in particular to be generated randomly, before a data block 7, 8 is fed into the electrical line means 3 (cf. FIG. 3). The average random delay time ΔT_{w} meets the following condition

ΔT_{w}≧N·T_{D}/ΔC_{R}

where N is the number of photovoltaic modules in the series, T_{D} is the time which is required for the transmission of a data block, and ΔC_{R} represents the average error rate as a result of the collision of data blocks. The average error rate ΔC_{R} is preferably in a range of from 10⁻¹ to 10⁻⁶, preferably 10⁻² to 10⁻⁵. With a value of 10⁻³, for example, there is a collision with 1000 data blocks.

The duration of the transmission of a data block 11 or 12 is approximately 2 ms, for example. If an average transmission rate of the data blocks of 15 seconds is assumed given a number of 8 photovoltaic modules in a series, only one data block of a thousand data blocks is lost as a result of collision.

On the basis of the plausibility data, it is possible for the evaluation unit 10, in the event of a collision of data blocks 7, 8 in which the data blocks are changed, to sort out selectively these changed, i.e. defective data blocks.

A conventional 8-bit microcontroller with timer function (for example SOIC20, 8 bit/8ch ADC) can be used as microcontroller 5.

The data blocks transmitted via the electrical line means are written to the evaluation unit 10, to be precise firstly the data elements 11 relating to the identification of the specific photovoltaic module and the data elements 31 relating to the status parameters of the respective photovoltaic module, such as the measured current, for example. These data are read in the evaluation unit 10, for example via the use of a shunt resistor, which is merely connected in phases.

FIG. 4 shows the arrangement of a plurality of photovoltaic modules in a series, wherein the voltage which is generated by a photovoltaic module series is measured. The sum of all of the voltages read by the individual test devices 11, 12 should correspond to the voltage actually measured by the evaluation unit 10. This makes it possible to determine the energy of the device directly. Furthermore, theft prevention can be realized when the test devices 11, 12 are not in operation owing to insufficient solar activity. Owing to this technology, the internal capacitance Cpv is a few degrees higher than the capacitance of the protective diode Cp in the junction box 14 or 15. The capacitance of N photovoltaic modules along a series is Cs=N×(Cpv+Cp). For the case where one or more photovoltaic modules are decoupled, the value Cs is substantially lower than Cp, with the result that information on a theft or a corresponding situation is thus provided.

The evaluation unit 10 is provided for making available data, in a wide variety of ways, as has already been described at the outset.

The illustration shown in FIG. 5A shows a first configuration of the present invention for enabling disconnection of the photovoltaic assembly 100 in an emergency situation. The reference numeral 43 denotes a string of a plurality of series-connected photovoltaic modules 40, 41 . . . . The string 43 can comprise a different number of photovoltaic modules, which is illustrated by the dashed line in FIG. 5A. As can be seen from FIG. 5A, a switching device in the form of a switch 61 is associated with each photovoltaic module 40, 41 etc. The switch 61 is in series with the electrical line means 42, which connect the positive output of the photovoltaic module 40 to the negative input of the adjacent photovoltaic module 41, in FIG. 5A. The switch 61 is preferably located in the junction box 47 and is actuated by the test device 45, i.e. the microcontroller 5 located there of the respective photovoltaic module 40 or 41.

In order to trigger the actuation of the respective switch 61, a single disconnection signal is generated and fed into the electrical line means 42 of the string 43 of individual photovoltaic modules 40, 41. This may be a modulated voltage signal which is fed into the series circuit of photovoltaic modules 40, 41 at a suitable point. The electrical line means 42 of the string 43 are in contact with a reception circuit 49 (PVMS board) of a respective string. Within the reception circuit 49, individual status data transmitted unidirectionally by the respective photovoltaic modules 40, 41 (cf. the type of transmission according to the details given in respect of FIGS. 1-4) are read, fed via a frequency filter 55 and the evaluation unit 10 (PVMS server, cf. FIG. 1), for example, and further-processed there. An inverter is associated with the reception circuit 49 and serves the purpose of transforming the DC voltage present at the reception circuit 49 into an AC voltage.

The test device 45 which corresponds to the test device shown in FIG. 2 and has a microcontroller 5, is located in the junction box 47.

The configuration of the present invention illustrated in FIG. 5B differs from the configuration illustrated in FIG. 5A in that, instead of the switch 61 for interrupting the electrical line means 42, a short-circuiting switch 62 is provided, which short-circuits the input and output of the potential of the photovoltaic cells of the respective photovoltaic module 40, 41. The actuation of this short-circuiting switch 62 via a disconnection signal is the same as in FIG. 5A.

FIG. 6 shows the current intensity/voltage graph for the operation of photovoltaic modules. Given a specific ratio of current intensity A to voltage V, the electrical power W generated by the photovoltaic modules is at its greatest (peak of curve W in FIG. 6). This corresponds to the so-called MPP point (maximum power point). The rectifier 44 of the reception circuit 49 of the string 43 has control electronics for ensuring the so-called MPP tracking or the MPP regulation. The object of the MPP tracking or the MPP regulation consists in matching the inverter 44 to continuously changing environmental conditions and thus always generating the maximum possible power. The regulator or controller of the inverter 44 sets a specific setpoint voltage value and measures the power fed into the grid. Then, this setpoint value easily changes into a positive or negative value. If the “new” power that is thereupon fed in and is measured after the slight change in the input voltage is greater than the previous measured power, in a next step the voltage is changed in the same direction as in the preceding step. If the power has decreased, the direction of the change is reversed. This regulation is software-controlled.

The software-controlled regulation of the MPP tracking or the MPP regulation is now used in accordance with the invention to generate the disconnection signal directly by the inverter 44, for example in the form of a voltage pattern which is identified by the test device 45, with the result that said test device actuates the switch 61 or short-circuiting switch 62. The advantage of this solution consists in that only a change in the MPP software of the inverter 44 is required, as a result of which a very inexpensive solution for emergency disconnection is provided.

Alternatively, the disconnection signal can also be generated by an additionally provided signal generator 70, as is illustrated in FIG. 7. The signal generator 70 comprises a load element 52, for example in the form of a capacitor, with which a load, for example a voltage, can be generated. The load element 52 is connected to an active element, for example in the form of a power transistor 51, which generates a modulated signal, for example a sequence of a plurality of square-wave voltage pulses 50, and feeds it into the electrical line means 42. This voltage signal passes through the electrical line means 42 which connect the individual photovoltaic modules 40, 41 to one another and is received by each individual photovoltaic module 40, 41. Owing to the shape of the voltage signal, this signal is not interpreted as a signal for a status parameter of the respective photovoltaic module 40, 41 but as a disconnection signal.

The illustration of the photovoltaic modules connected in series in FIG. 7 is simplified. The features as can be identified from FIGS. 1, 2 and 5 have been omitted in FIG. 7 for reasons of clarity. Once the disconnection signal 50 has been received by the individual photovoltaic modules 40, 41, all of the photovoltaic modules are disconnected by actuation of the switch 61 or 62.

Express reference is made to the fact that partial combinations of features of the described embodiment are also claimed as being essential to the invention.

### LIST OF REFERENCE SYMBOLS

1 Photovoltaic module
2 Photovoltaic module
3 Electrical line means
4 Electrical line means
5 Microcontroller
6 Data element
7 Data block
8 Data block
9 Photovoltaic cell
10 Evaluation unit
11 Data element
12 Test device
13 Test device
14 Junction box
15 Junction box
16 Interface
17 Interface
18 Interface
19 Interface
20 Photovoltaic assembly
21 Com port
22 Optical interface
23 Internet connection
24 GSM connection
25 Energy source
26 Switching means
27 Voltage input
28 Data input
29 Current signal input
30 Photons
31 Data element
32 Diode
33 Resistor
40 Photovoltaic module
41 Photovoltaic module
42 Electrical line means
43 String
44 Inverter
45 Junction box
46 Voltage signal
47 Junction box
48 Junction box
49 Reception circuit/string
50 Disconnection signal
51 Power transistor
52 Load element
53 Interrupter element
54 Reception unit for status signals
55 Frequency filter
61 Switch
62 Short-circuiting switch
70 Signal generator
100 Photovoltaic assembly

1. A method for disconnecting a photovoltaic assembly, wherein the photovoltaic assembly comprises the following:
a string consisting of several photovoltaic modules comprising a plurality of solar cells, electrical line means which connect the individual photovoltaic modules to one another to form the string and which serve the purpose of conducting the current produced by the individual solar cells in the photovoltaic modules to a common inverter, wherein
disconnection of the photovoltaic assembly is performed in a hazardous situation by means of a disconnection signal, as a result of which interruption of the electrical line means takes place at the respective photovoltaic module,
the disconnection signal is conducted via the electrical line means to the individual photovoltaic modules in the string,
the disconnection signal is detected at the respective photovoltaic module,
the respective photovoltaic module is disconnected via a switching device arranged at the respective photovoltaic module,
determination of at least one status parameter of the respective photovoltaic module is implemented by a test circuit associated with the respective photovoltaic module, and
the disconnection signal can be detected as a further signal which can be sensed by the test circuit,
wherein
a modulated voltage or current signal is fed into the electrical line means in order to trigger the disconnection operation, and
a central evaluation unit is provided which receives the information relating to the status of the photovoltaic modules via the electrical line means.

2. The method as claimed in claim 1, wherein the electrical line means are interrupted for disconnection of the respective photovoltaic module.

3. The method as claimed in claim 1, wherein a short circuit is connected for disconnecting the respective photovoltaic module.

4. The method as claimed in claim 1, wherein control of the current/voltage characteristic takes place at the inverter (MPP tracking) and the disconnection signal is generated by the inverter as a signal in the context of this control.

5. The method as claimed in at claim 1, wherein the voltage or the current intensity is modulated for generating the disconnection signal.

6. The method as claimed in claim 5, wherein voltage pulses with a relatively high frequency are provided as disconnection signal.

7. A photovoltaic assembly comprising
at least one string consisting of several photovoltaic modules comprising a plurality of solar cells,
electrical line means which connect the individual photovoltaic modules to one another to form the string and which serve the purpose of conducting the current produced by the individual solar cells in the photovoltaic modules to a common inverter,
a disconnection device of the photovoltaic assembly in a hazardous situation,
a device for generating a disconnection signal which is common to the photovoltaic modules is provided, and
a switching device is associated with each photovoltaic module, by means of which switching device the respective photovoltaic module can be disconnected when the disconnection signal is input, by virtue of an interruption of the electrical line means taking place at the respective photovoltaic module,
the test device of the respective photovoltaic module has a test circuit for the status determination which at the same time acts as a device for receiving the disconnection signal, and
the disconnection signal can be detected as a further signal which can be sensed by the test circuit,
wherein
a modulated voltage or current signal can be fed into the electrical line means in order to trigger the disconnection operation, and
a central evaluation unit is provided which receives the information relating to the status of the photovoltaic modules.

8. The photovoltaic assembly as claimed in claim 7, wherein the switching device is a switch which interrupts the electrical line means.

9. The photovoltaic assembly as claimed in claim 7, wherein the switching device is a short-circuiting switch.

10. The photovoltaic assembly as claimed in claim 7,
wherein the controller of the inverter has control software for the current/voltage characteristic (MPP tracking), and a subroutine of the generation of the disconnection signal is provided.

11. The photovoltaic assembly as claimed in claim 7, wherein a signal generator for generating the disconnection signal is provided.

12. The photovoltaic assembly as claimed in claim 11,
wherein the signal generator comprises a load element and a transistor.

13. The photovoltaic assembly as claimed in claim 7, wherein a signal modulated with respect to the voltage or the current intensity is provided as disconnection signal.

14. The photovoltaic assembly as claimed in claim 7, wherein voltage pulses with a relatively high frequency are provided as disconnection signal.

15. A method for disconnecting a photovoltaic assembly, wherein the photovoltaic assembly comprises the following:
a string consisting of several photovoltaic modules comprising a plurality of solar cells,
electrical line means which connect the individual photovoltaic modules to one another to form the string and which serve the purpose of conducting the current produced by the individual solar cells in the photovoltaic modules to a common inverter, wherein
disconnection of the photovoltaic assembly is performed in a hazardous situation by means of a disconnection signal, as a result of which interruption of the electrical line means takes place at the respective photovoltaic module,
the disconnection signal is conducted via the electrical line means to the individual photovoltaic modules in the string,
the disconnection signal is detected at the respective photovoltaic module,
the respective photovoltaic module is disconnected via a switching device arranged at the respective photovoltaic module,
determination of at least one status parameter of the respective photovoltaic module is implemented by a test circuit associated with the respective photovoltaic module, and
the disconnection signal can be detected as a further signal which can be sensed by the test circuit,
wherein
a modulated voltage or current signal is fed into the electrical line means in order to trigger the disconnection operation, and
a central evaluation unit is provided which receives the information relating to the status of the photovoltaic modules via the electrical line means, wherein
the disconnection signal is one which is common to the photovoltaic modules.

16. A photovoltaic assembly comprising
at least one string consisting of several photovoltaic modules comprising a plurality of solar cells,
electrical line means which connect the individual photovoltaic modules to one another to form the string and which serve the purpose of conducting the current produced by the individual solar cells in the photovoltaic modules to a common inverter,
a disconnection device of the photovoltaic assembly in a hazardous situation,
a device for generating a disconnection signal which is common to the photovoltaic modules is provided, and
a switching device is associated with each photovoltaic module, by means of which switching device the respective photovoltaic module can be disconnected when the disconnection signal is input, by virtue of an interruption of the electrical line means taking place at the respective photovoltaic module,
the test device of the respective photovoltaic module has a test circuit for the status determination which at the same time acts as a device for receiving the disconnection signal, and
the disconnection signal can be detected as a further signal which can be sensed by the test circuit,
wherein
a modulated voltage or current signal can be fed into the electrical line means in order to trigger the disconnection operation, and
a central evaluation unit is provided which receives the information relating to the status of the photovoltaic modules, wherein
the disconnection signal is one which is common to the photovoltaic modules.
